(19) United States
(12) Patent Application Publication
(10) Pub. No.: US 2025/0022810 A1
(43) Pub. Date: Jan. 16, 2025

(54) SEMICONDUCTOR PACKAGE SUBSTRATE WITH STRESS BUFFER PADS AND METHODS FOR MAKING THE SAME

(71) Applicant: Taiwan Semiconductor Manufacturing Company Limited, Hsinchu (TW)

(72) Inventors: Chung-Hsin Chen, Hsinchu City (TW); Chi Wei Hsu, New Taipei City (TW); Sih Han Chen, Hsinchu City (TW); Yi Chung Chen, Taoyuan City (TW)

(21) Appl. No.: 18/349,412

(22) Filed: Jul. 10, 2023

(51) Int. Cl. H01L 23/00; H01L 21/48; H01L 23/498; H01L 23/538; H01L 25/065

(52) U.S. Cl. CPC H01L 23/562; H01L 21/4857; H01L 23/49811; H01L 23/49822; H01L 23/49838; H01L 23/5385; H01L 25/0655; H01L 24/16; H01L 24/32; H01L 24/73; H01L 2224/16227; H01L 2224/32225; H01L 2224/73204

(57) ABSTRACT

A package substrate and a method of fabrication thereof including stress buffer layers. Each stress buffer layer may be vertically spaced from and at least partially overlap with a corresponding bonding pad of the package substrate. The stress buffer pads may provide structural reinforcement to distribute tensile stress on the package substrate and inhibit warpage and crack formation in the package substrate. Accordingly, semiconductor package reliability and yields may be improved.

### BACKGROUND

Semiconductor devices are used in a variety of electronic applications. Some examples may include personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer, and individual dies on the wafer are singulated by sawing between the integrated circuits along a scribe line. The individual dies are typically packaged separately, for example, in multi-chip modules, or in other types of packaging. As semiconductor packages have become larger and more complex, ensuring mechanical integrity of the package has become more difficult.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-section view of an exemplary intermediate structure during a process of forming a package substrate including a substrate core including a first surface and a second surface opposite the first surface according to various embodiments of the present disclosure.

FIG. 2 is a vertical cross-section view of an exemplary intermediate structure during a process of fabricating a package substrate illustrating core metal features over the first surface and the second surface of the substrate core and a plurality of conductive vias extending through the substrate core according to various embodiments of the present disclosure.

FIG. 3 is a vertical cross-section view of an exemplary intermediate structure during a process of fabricating a package substrate illustrating first redistribution structures formed over the first surface of the substrate core according to various embodiments of the present disclosure.

FIG. 4 is a vertical cross-section view of a package substrate including second redistribution structures including stress buffer pads formed over the second surface of the substrate core according to various embodiments of the present disclosure.

FIG. 5A is an enlarged vertical cross-section view of region A of the package substrate shown in FIG. 4 according to an embodiment of the present disclosure.

FIG. 5B is a horizontal cross-section view of a portion of the package substrate taken along line B-B′ in FIG. 5A.

FIG. 5C is a horizontal cross-section view of a portion of the package substrate taken along line C-C′ in FIG. 5A.

FIG. 6A is an enlarged vertical cross-section view of region A of the package substrate shown in FIG. 4 according to another embodiment of the present disclosure.

FIG. 6B is a horizontal cross-section view of a portion of the package substrate taken along line B-B′ in FIG. 6A.

FIG. 6C is a horizontal cross-section view of a portion of the package substrate taken along line C-C′ in FIG. 6A.

FIG. 7A is a vertical cross-section view of a portion of a package substrate according to yet another embodiment of the present disclosure.

FIG. 7B is a horizontal cross-section view of the portion of the package substrate taken along line B-B′ in FIG. 7A.

FIG. 7C is a horizontal cross-section view of the portion of the package substrate taken along line C-C′ in FIG. 7A.

FIG. 8A is a vertical cross-section view of a portion of a package substrate according to yet another embodiment of the present disclosure.

FIG. 8B is a horizontal cross-section view of the portion of the package substrate taken along line B-B′ in FIG. 8A.

FIG. 8C is a horizontal cross-section view of the portion of the package substrate taken along line C-C′ in FIG. 8A.

FIG. 9A is a vertical cross-section view of a portion of a package substrate according to yet another embodiment of the present disclosure.

FIG. 9B is a horizontal cross-section view of the portion of the package substrate taken along line B-B′ in FIG. 9A.

FIG. 9C is a horizontal cross-section view of the portion of the package substrate taken along line C-C′ in FIG. 9A.

FIG. 10A is a vertical cross-section view of a portion of a package substrate according to yet another embodiment of the present disclosure.

FIG. 10B is a horizontal cross-section view of the portion of the package substrate taken along line B-B′ in FIG. 10A.

FIG. 10C is a horizontal cross-section view of the portion of the package substrate taken along line C-C′ in FIG. 10A.

FIG. 11A is a vertical cross-section view of a portion of a package substrate according to yet another embodiment of the present disclosure.

FIG. 11B is a horizontal cross-section view of the portion of the package substrate taken along line B-B′ in FIG. 11A.

FIG. 11C is a horizontal cross-section view of the portion of the package substrate taken along line C-C′ in FIG. 11A.

FIG. 12A is a vertical cross-section view of a portion of a package substrate according to yet another embodiment of the present disclosure.

FIG. 12B is a horizontal cross-section view of the portion of the package substrate taken along line B-B′ in FIG. 12A.

FIG. 12C is a horizontal cross-section view of the portion of the package substrate taken along line C-C′ in FIG. 12A.

FIG. 12D is a horizontal cross-section view of the portion of the package substrate taken along line D-D′ in FIG. 12A.

FIG. 13A is a vertical cross-section view of a portion of a package substrate 120 according to yet another embodiment of the present disclosure.

FIG. 13B is a horizontal cross-section view of the portion of the package substrate taken along line B-B′ in FIG. 13A.

FIG. 13C is a horizontal cross-section view of the portion of the package substrate taken along line C-C′ in FIG. 13A.

FIG. 14 is a vertical cross-section view of a semiconductor package including a package structure mounted over the first outer surface of a package substrate including a plurality of stress buffer pads according to various embodiments of the present disclosure.

FIG. 15 is a vertical cross-section view of a semiconductor package including a second underfill material portion located between the first outer surface of the package substrate and the lower surface of the interposer according to various embodiments of the present disclosure.

FIG. 16 is a vertical cross-section view of a semiconductor package mounted to a supporting substrate according to various embodiments of the present disclosure.

FIG. 17 is a vertical cross-section view of a semiconductor package mounted to a supporting substrate including a third underfill material portion according to various embodiments of the present disclosure.

FIG. 18 is a flowchart illustrating a method of fabricating a package substrate according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein may be directed to semiconductor devices, and in particular to a substrate for a semiconductor package that includes stress buffer pads, and methods of fabrication thereof.

Typically, in a semiconductor package a number of semiconductor integrated circuit (IC) dies (i.e., “chips”) may be mounted onto a common substrate, which may also be referred to as a “package substrate.” In some packages, such as in a fan out wafer level package (FOWLP) and/or fan-out panel level package (FOPLP), a plurality of semiconductor IC dies may be mounted to an interposer, such as an organic interposer or a semiconductor (e.g., silicon) interposer, that may include interconnect structures extending therethrough. The resulting package structure, including the interposer and the semiconductor IC dies mounted thereon, may then be mounted onto a surface of a package substrate using solder connections to form a semiconductor package. The semiconductor package, including the package substrate and the package structure mounted thereon, may then be mounted to a supporting substrate, such as a printed circuit board (PCB).

As semiconductor packages have become larger and more complex by integrating greater numbers of semiconductor IC dies, ensuring the mechanical stability of the semiconductor package has become more important. In many semiconductor packages, mechanical stresses on various components of the semiconductor package, such as the package substrate, may cause warpage and cracking to occur within the components. This may result in an increasing failure rate and decreased reliability of the semiconductor package.

Various embodiments disclosed herein include package substrates and methods of fabricating package substrates that include stress buffer pads. In various embodiments, a package substrate may include a substrate core having a first surface and a second surface that is opposite to the first surface. Redistribution structures including conductive interconnect structures embedded in a dielectric material may be located over the first surface and the second surface of the substrate core. The redistribution structures may also include a first plurality of bonding pads on a first side of the package substrate, a second plurality of bonding pads on a second side of the package substrate, and protective coating layers (e.g., solder resist layers) defining respective first and second outer surfaces of the package substrate. The first plurality of bonding pads may be configured to bond a first side of the package substrate to a semiconductor package structure including one or more semiconductor integrated circuit (IC) dies, and the second plurality of bonding pads may be configured to bond a second side of the package substrate to a support substrate, such as a printed circuit board (PCB). At least one stress buffer pad may be located within the redistribution structures proximate to the second side of the package substrate and may be vertically spaced from and at least partially overlap with a corresponding bonding pad of the second plurality of bonding pads. The stress buffer pad may provide structural reinforcement that may distribute tensile stress on the package substrate and thereby inhibit warpage and crack formation in the package substrate. Accordingly, semiconductor package reliability and yields may be improved.

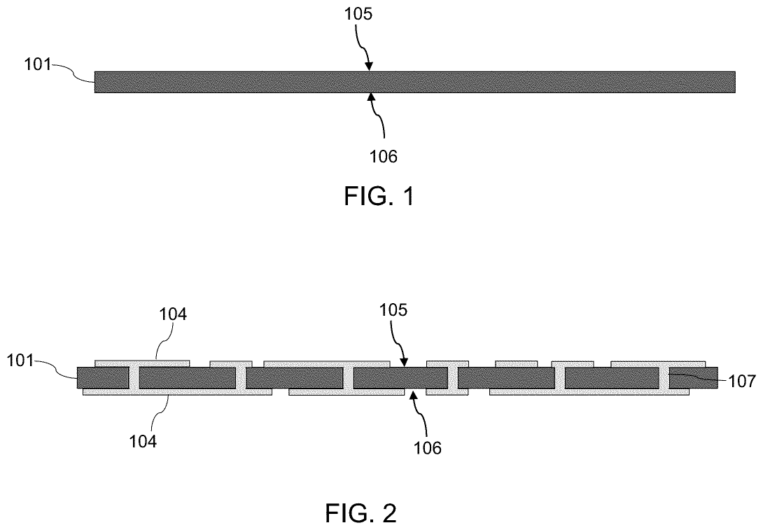

FIGS. 1-4 are sequential vertical cross-section views of an exemplary intermediate structures that are formed during a process of fabricating a package substrate according to various embodiments of the present disclosure. Referring to FIG. 1, a substrate core 101 is illustrated. The substrate core 101 includes a first surface 105 and a second surface 106 that is opposite the first surface 105. In some embodiments, the substrate core 101 may be composed of a sheet of laminate reinforced resin. The laminate reinforced resin sheet may include a reinforcement material (e.g., glass fiber or cloth) that is impregnated with a resin system, such as an epoxy-based resin system, and is cured under heat and pressure to form a sheet of laminate reinforced resin. In some embodiments, a layer of conductive material (e.g., copper foil) may be provided over the upper and lower surfaces of the stack during the lamination process to provide a substrate core 101 including layers of conductive material (not shown in FIG. 1) over the first surface 105 and the second surface 106 of the substrate core 101. Other suitable materials and constructions for the substrate core 101 are within the contemplated scope of disclosure. In various embodiments, the substrate core 101 may have a thickness between the first surface 105 and the second surface 106 that is between about 0.4 mm and about 1.5 mm, although thicker or thinner dimensions may be used.

FIG. 2 is a vertical cross-section view of an exemplary intermediate structure during a process of fabricating a package substrate illustrating core metal features 104 over the first surface 105 and the second surface 106 of the substrate core 101 and a plurality of conductive vias 107 extending through the substrate core 101 according to various embodiments of the present disclosure. Referring to FIG. 2, a plurality of through-holes may be formed through the substrate core 101 extending between the first surface 105 and the second surface 106 of the substrate core 101. The through-holes may be formed using any suitable process, such as mechanical drilling, laser drilling, or an etching process through a photolithographically-patterned mask. Other suitable processes for forming the through-holes are within the contemplated scope of disclosure.

Referring again to FIG. 2, a plurality of conductive vias 107 may be formed within each of the through-holes such that the conductive vias 107 extend between the first surface 105 and the second surface 106 of the substrate core 101. The conductive vias 107 may be formed of a suitable conductive material, such as Cu, Ni, W, Al, Co, Mo, Ru, and the like, including combinations and alloys thereof. Other suitable materials for the conductive vias 107 are within the contemplated scope of disclosure. The plurality of conductive vias 107 may be formed using a suitable deposition process, such as an electrochemical deposition process (e.g., electroplating). Other suitable deposition processes are within the contemplated scope of disclosure.

Referring again to FIG. 2, core metal features 104 may be formed over the first surface 105 and the second surface 106 of the substrate core 101. In some embodiments, the core metal features 104 may be formed by providing layers of a conductive material (e.g., a copper clad laminate) over the first surface 105 and the second surface of the substrate core 101. In some embodiments, the layers of conductive material may be formed during the lamination process used to form the substrate core 101, as described above with reference to FIG. 1. Alternatively, or in addition, the layers of conductive material may be formed, in whole or in part, over the first surface 105 and the second surface 106 of the substrate core 101 using a suitable deposition process, such as an electroplating process. The layers of conductive material may be patterned via an etching process performed through a photolithographically-patterned mask to form discrete core metal features 104 (e.g., copper traces) over the first surface 105 and the second surface 106 of the substrate core 101. The core metal features 104 may be electrically coupled to one or more conductive vias 107.

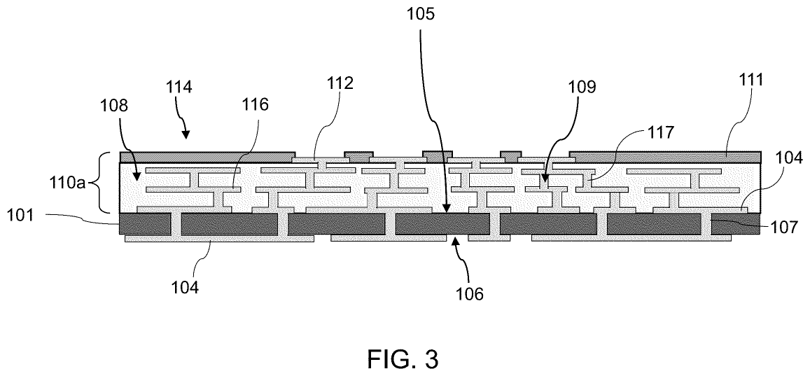

FIG. 3 is a vertical cross-section view of an exemplary intermediate structure during a process of fabricating a package substrate illustrating first redistribution structures 110a formed over the first surface 105 of the substrate core 101 according to various embodiments of the present disclosure. The first redistribution structures 110a may include a plurality of conductive interconnect structures 109 (e.g., metal lines 116 and vias 117) embedded in a dielectric material 108. The first redistribution structures 110a may further include a first plurality of bonding pads 112 and a passivation layer 111 formed over the dielectric material 108 and the conductive interconnect structures 109. In various embodiments, the first redistribution structures 110a may be located between the first surface 105 of the substrate core 101 and a semiconductor package structure including one or more semiconductor IC dies (or “chips”) in an assembled semiconductor package. Thus, the first redistribution structures 110a may also be referred to as “chip-side” redistribution structures 110a.

Referring to FIG. 3, the first redistribution structures 110a may be formed by providing a first layer of dielectric material 108 over the first surface 105 of the substrate core 101 and the core metal features 104. The first layer of dielectric material 108 may include a polymer-based dielectric material, such as an Ajinomoto Buildup Film (ABF)® product from Ajinomoto Co., Inc., Tokyo, JP. Other suitable dielectric materials are within the contemplated scope of disclosure. In some embodiments, the first layer of dielectric material 108 may be applied as a film over the first surface 105 of the substrate core 101 and the core metal features 104. The film may be vacuum laminated over the first surface 105 of the substrate core 101 and the core metal features 104 and may be partially cured (e.g., via a hot-pressing process). A plurality of through-holes may be formed through the first layer of dielectric material 108 using a suitable process, such as by mechanical drilling, laser drilling, and/or an etching process. A core metal features 104 and/or a conductive via 107 may be exposed at the bottom of each of the through-holes.

A metallization process may be used to form a first plurality of vias 117 within the through-holes through the first layer of dielectric material 108. The first plurality of vias 117 may be formed using a suitable deposition process, such as electroplating. The deposition process may also form a second layer of conductive material over the first layer of dielectric material 108. Alternatively, a separate deposition process may be used to form a second layer of conductive material over the first layer of dielectric material 108. The second layer of conductive material may be patterned via an etching process performed through a photolithographically-patterned mask to form a plurality of metal lines 116 (e.g., copper traces) over the surface of the first layer of dielectric material 108. A second layer of dielectric material 108 may be formed over the plurality of metal lines 116 as described above, and a plurality of through-holes may be formed through the second layer of dielectric material 108. An additional metallization process may be used to form a second plurality of vias 117 within the through-holes formed through the second layer of dielectric material 108. These processes may optionally be repeated a number of times to form the first redistribution structures 110a including a plurality of conductive interconnect structures 109 (e.g., metal lines 116 and vias 117) embedded in a dielectric material 108. The layers of the dielectric material 108 may optionally be subjected to curing process at an elevated temperature (e.g., 170-200° C.) to form a solid dielectric material 108 surrounding the conductive interconnect structures 109. A first plurality of bonding pads 112 may be formed over the uppermost layer of the dielectric material 108. A passivation layer 111 may also be formed over the uppermost layer of the dielectric material 108. The first plurality of bonding pads 112 may be exposed through openings in the passivation layer 111. The passivation layer 111 may define a first outer surface 114 of a package substrate. The passivation layer 111 may provide a protective coating for the package substrate. The passivation layer 111 may also inhibit solder material from adhering to the first outer surface 114 of the package substrate during a subsequent solder reflow process.

In various embodiments, the passivation layer 111 may include a solder resist material. The passivation layer 111 formed of solder resist material may also be referred to as a “solder mask.” The solder resist material of the passivation layer 111 may include a suitable resin material that is resistant to humidity and high-temperature, and to which a solder material will not strongly adhere. The solder resist material of the passivation layer 111 may be formed using a suitable deposition process, such as via screen printing, spraying, and/or vacuum lamination. Other suitable deposition processes are within the contemplated scope of disclosure.

FIG. 4 is a vertical cross-section view of a package substrate 120 including second redistribution structures 110b formed over the second surface 106 of the substrate core 101 according to various embodiments of the present disclosure. Referring to FIG. 4, the second redistribution structures 110b over the second surface 106 of the substrate core 101 may include a plurality of conductive interconnect structures 109 (e.g., metal lines 116 and vias 117) embedded in a dielectric material 108, a second plurality of bonding pads 113 and a passivation layer 111 formed over the dielectric material 108 and the conductive interconnect structures 109. The passivation layer 111 of the second redistribution structures 110b may define a second outer surface 115 of the package substrate 120 that is opposite the first outer surface 114. The second redistribution structures 110b over the second surface 106 of the substrate core 101 may include a similar construction and may be formed using similar or identical processes to the first redistribution structures 110a formed over the first surface 105 of the substrate core 101 as described above with reference to FIG. 3. Thus, repeated discussion of like features is omitted for brevity. Further, although FIG. 3 and FIG. 4 illustrate an embodiment in which the first redistribution structures 110a are formed over the first surface 105 of the substrate core 101 prior to the formation of the second redistribution structures 110b over the second surface 106 of the substrate core 101, it will be understood that all or a portion of the second redistribution structures 110b over the second surface 106 of the substrate core 101 may be formed prior to the formation of the first redistribution structures 110a over the first surface 105 of the substrate core 101, or the first redistribution layer 110a and second redistribution layer 110b (collectively, redistribution layers 110) may be formed at the same time over the first surface 105 and the second surface 106 of the substrate core 101.

Referring again to FIG. 4, the second redistribution structures 110b may be located between the second surface 106 of the substrate core 101 and a supporting substrate (e.g., printed circuit board (PCB)) in the assembled semiconductor package. Thus, the second redistribution structures 110b may also be referred to as “board-side” redistribution structures 110b. The first plurality of bonding pads 112 of the first redistribution structures 110a may be configured to electrically connect the package 120 substrate to a semiconductor package structure including at least one semiconductor IC die, and the second plurality of bonding pads 113 of the second redistribution structures 110b may be configured to electrically connect the package substrate 120 to a supporting substrate, such as a PCB.

As discussed above, mechanical stresses on various components of a semiconductor package, including the package substrate 120, may result in warpage and crack formation within the package substrate 120. This may increase the failure rate and decrease the reliability and/or yields of the semiconductor packages. In the case of a package substrate 120 as shown in FIG. 4, for example, differences in the amount of shrinkage between the passivation layer 111 (e.g., a solder mask layer, a polymer layer, a dielectric layer, an oxide layer, a nitride layer, or combinations thereof) and the dielectric material 108 (e.g., a buildup film, an organic material layer, a polymer film, an oxide layer, a nitride layer or combinations thereof) may impart tensile stress on the package substrate 120. These stresses often concentrate in certain areas of the package substrate 120, such as in regions of the “board-side” of the package substrate 120 in which there are minimal, if any, conductive interconnect structures 109 located between the bonding pads 113 and the core metal features 104 on the second surface 106 of the substrate core 101. Accordingly, these regions of concentrated tensile stress may result in warping of the package substrate 120 and the formation of cracks through the passivation layer 111 around the periphery of the bonding pads 113 and into the dielectric material 108 of the second redistribution structures 110b. This may negatively affect the integrity and performance of the package substrate 120.

Package substrates 120 according to various embodiments of the present disclosure may include at least one stress buffer pad 103 in the second (i.e., “board-side”) redistribution structures 110b of the package substrate 120. FIG. 4 illustrates a plurality of stress buffer pads 103 located within the second redistribution structures 110b of the package substrate 120. Each of the stress buffer pads 103 may be spaced from, and may at least partially overlie (i.e., overlap with), a bonding pad 113 of the second plurality of bonding pads 113. FIG. 4 shows an embodiment in which stress buffer pads 103 are located over a first subset of the bonding pads 113 of the second plurality of bonding pads 113, and a stress buffer pad 103 not present over a second subset of the bonding pads 113. However, it will be understood that in other embodiments stress buffer pads 103 may be present over all of the bonding pads 113 of the second plurality of bonding pads 113. In various embodiments, the at least one stress buffer pad 103 may mitigate the stress on the passivation layer 111 and may also help to isolate stress on the passivation layer 111 from the overlying dielectric material 108 of the second redistribution structures 110b. Accordingly, the risk of crack formation in the second redistribution structures 110b may be reduced, and semiconductor package reliability and yields may be improved.

In some embodiments, the stress buffer pads 103 may be composed of a suitable conductive material, such as Cu, Ni, W, Al, Co, Mo, Ru, and the like, including combinations and alloys thereof. In some embodiments, the stress buffer pads 103 may be formed of the same material(s) as the conductive interconnect structures 109 (e.g., metal lines 116 and vias 117) and/or the bonding pads 112, 113 of the second redistribution structures 110b. The stress buffer pads 103 may be formed during the process used to form the second redistribution structures 110b as described above. In particular, the stress buffer pads 103 may be formed by depositing a layer of conductive material over a layer of the dielectric material 108 using a suitable deposition process, and may be patterned via an etching process performed through a photolithographically-patterned mask to form a plurality of discrete stress buffer pads 103. One or more additional layers of the dielectric material 108 may then be deposited over the stress buffer pads 103, and the bonding pads 113 may be formed over the one or more additional layers of the dielectric material 108. The stress buffer pads 103 may be electrically coupled to the conductive interconnect structures 109 and/or the bonding pads 113 of the second redistribution structures 110b, or may be electrically isolated from the conductive interconnect structures 109 and/or the bonding pads 113 of the second redistribution structures 110b, as described in further detail below.

In some embodiments, all or a portion of the stress buffer pads 103 may be composed of a material having a higher Young's modulus than the Young's modulus of the material(s) of the conductive interconnect structures 109 and/or the bonding pads 113 of the second redistribution structures 110b. For example, where the conductive interconnect structures 109 and the bonding pads 113 of the second redistribution structures 110b are composed of copper (Young's modulus=130 GPa), the stress buffer pads 103 may be composed of a material having a Young's modulus greater than 130 GPa, such as greater than 200 GPa, including greater than 300 GPa. In some embodiments, the stress buffer pads 103 may be composed of a ceramic material, such as Al₂O₃, AlN, etc., and/or a semiconductor material, such as Si. Other suitable materials for the stress buffer pads 103 are within the contemplated scope of disclosure.

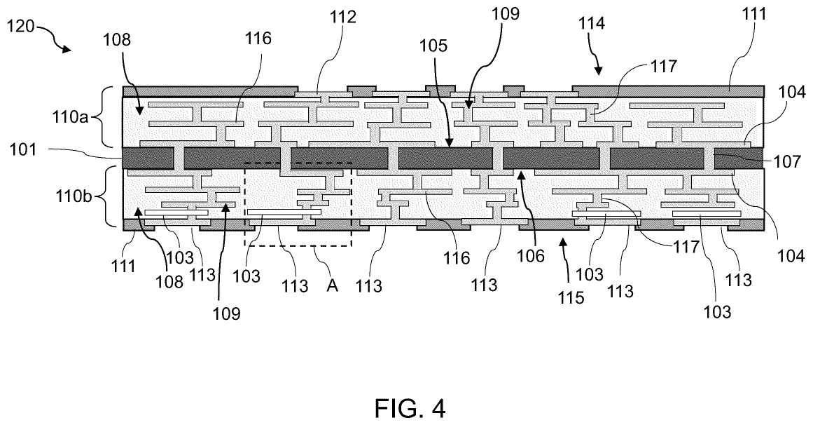

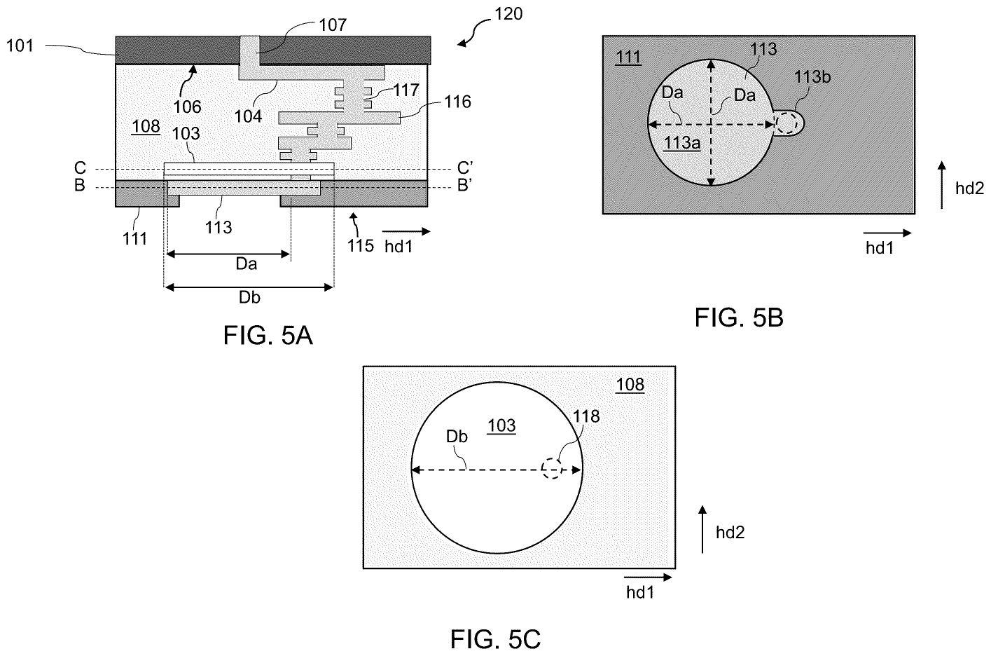

FIG. 5A is an enlarged vertical cross-section view of region A of the package substrate 120 shown in FIG. 4 according to an embodiment of the present disclosure. FIG. 5B is a horizontal cross-section view of a portion of the package substrate taken along line B-B′ in FIG. 5A. FIG. 5C is a horizontal cross-section view of a portion of the package substrate taken along line C-C′ in FIG. 5A. Referring to FIG. 5A, a stress buffer pad 103 is shown extending generally parallel to and vertically-spaced from a bonding pad 113 of the package substrate 120. The stress buffer pad 103 may be located between the bonding pad 113 and the substrate core 101 of the package substrate 120, and may at least partially overlie the bonding pad 113. In various embodiments, the stress buffer pad 103 may be located more proximate to the bonding pad 113 than to the second surface 106 of the substrate core 101. In one non-limiting embodiment, the vertical separation between the bonding pad 113 and the stress buffer pad 103 may be between about 20 μm and about 40 μm, although greater or lesser vertical separation distances may also be utilized, but is less than the thickness of the second redistribution structures 110b. The total vertical separation distance between the bonding pad 113 and the substrate core 101 may be between about 90 μm and about 450 μm in some embodiments, but is less than the thickness of the second redistribution structures 110b. The dielectric material 108 of the second redistribution structures 110b may be located between the bonding pad 113 and the overlying stress buffer pad 103. Thus, the bonding pad 113 and the stress buffer pad 103 may form a structure similar to a parallel-plate capacitor, where the bonding pad 113 and stress buffer pad 103 are vertically separated and at least partially overlap with one another.

In the embodiment shown in FIGS. 5A-5C, the bonding pad 113 may include a bonding pad region 113a and a via contact region 113b. At least a portion of the bonding pad region 113a may be exposed through an opening in the outer coating layer 111 (e.g., solder mask) to enable the bonding pad 113 to be mechanically and electrically coupled to a supporting substrate (e.g., a PCB) via a bonding material portion (e.g., a solder ball). The bonding pad region 113a in the embodiment of FIGS. 5A-5C has a circular shape, although it will be understood that the bonding pad region 113a may have a different shape, such as a polygonal, elliptical, or irregular shape. The via contact region 113b may extend laterally from a side of the bonding pad region 113a. The via contact region 113b may be sized and shaped to contact a via 117 of the conductive interconnect structures 109 of the second redistribution structures 110b of the package substrate 120. The bonding pad 113 may have a minimum width dimension, Da, equal to the shortest distance between peripheral edges of the bonding pad 113 through the center of the bonding pad region 113a. Thus, where the bonding pad region 113a has a circular shape as shown in FIGS. 5A and 5B, the minimum width dimension Da of the bonding pad 113 may be equal to the diameter of the bonding pad region 113a. In some embodiments, the minimum width dimension, Da, of the bonding pads 113 may be between about 450 μm and about 900 μm, although it will be understood that greater and lesser minimum width dimensions, Da, of the bonding pads 113 may be utilized.

Referring to FIGS. 5A and 5C, the stress buffer pad 103 in this embodiment has a disk-shape with a circular horizontal cross-section, although it will be understood that the stress buffer pad 103 may have a different shape, such as a polygonal, elliptical, or irregular shape. While the stress pad 103 may have the same horizontal cross-sectional shape as the bonding pad 113, as shown in FIGS. 5A-5C, the stress buffer pad 103 may have a different horizontal cross-sectional shape than the bonding pad 113 in other embodiments. The stress buffer pad 103 in this embodiment contacts the conductive interconnect structures 109 of the second redistribution structures 110b. In particular, a via 117 may contact the stress buffer pad 103 as indicated by the dashed line 118 in FIG. 5C. In embodiments in which the stress buffer pad 103 is composed of an electrically conductive material, a first via 117 may contact the upper surface of the stress buffer pad 103 and a second via 117 may contact the lower surface of the stress buffer pad 103 and extend between the stress buffer pad 103 and the via contact region 113b of the bonding pad 113. The first via 117 and the second via 117 may be aligned with one another, or may be laterally offset from one another. In other embodiments, a single via 117 may extend continuously through the thickness of the stress buffer pad 103 to the via contact region 113b of the bonding pad 113, such as in instances in which the stress buffer pad 103 is composed of a non-electrically conductive material.

The stress buffer pad 103 may have a minimum width dimension, Db, equal to the shortest distance between peripheral edges of the stress buffer pad 103 through the geometric center of the stress buffer pad 103. Thus, where the stress buffer pad 103 has a circular shape as shown in FIGS. 5A and 5C, the minimum width dimension Db of the stress buffer pad 103 may be equal to the diameter of the stress buffer pad 103. In various embodiments, the ratio of the minimum width dimension, Db, of the stress buffer pad 103 to the minimum width dimension, Da, of the bonding pad 113 may be at least 0.7, such as at least about 1.0. In some embodiments, Db/Da may be between 0.7 and ˜1.5. In various embodiments, providing a stress buffer pad 103 having a minimum width dimension Db that is at least about 70% of the minimum width dimension Da of the underlying bonding pad 113 may provide structural reinforcement that may distribute the tensile stress on the passivation layer 111 such that the stress does not concentrate around the periphery of the bonding pad 113. This may help to smooth out any deformation of the passivation layer 111 and inhibit crack formation in the package substrate 120.

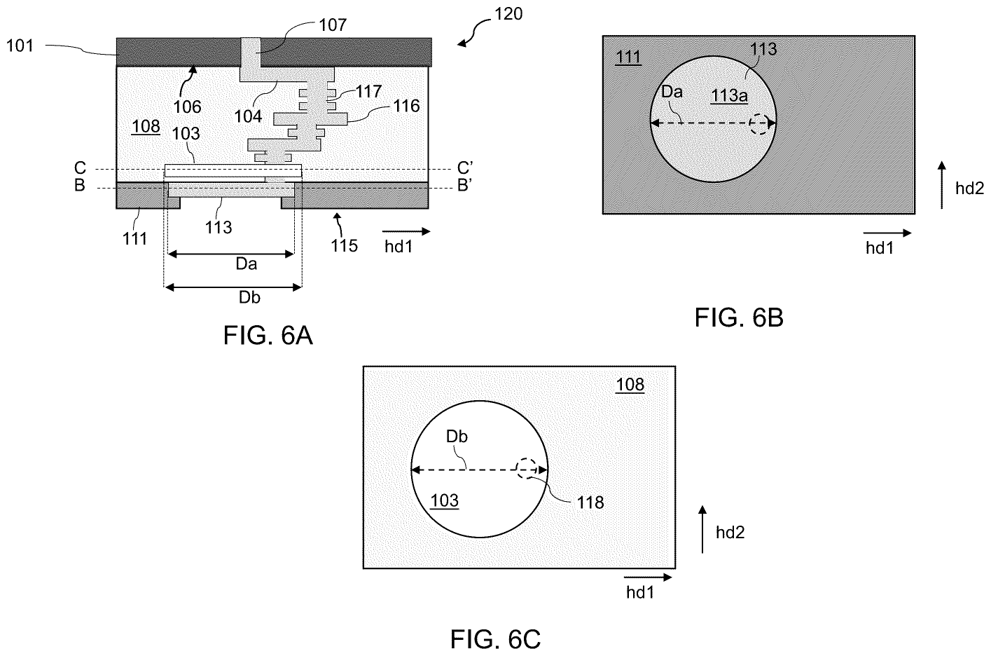

FIG. 6A is an enlarged vertical cross-section view of region A of the package substrate 120 shown in FIG. 4 according to another embodiment of the present disclosure. FIG. 6B is a horizontal cross-section view of a portion of the package substrate taken along line B-B′ in FIG. 6A. FIG. 6C is a horizontal cross-section view of a portion of the package substrate taken along line C-C′ in FIG. 6A. The package substrate 120 of FIGS. 6A-6C is similar to the package substrate 120 described above with reference to FIGS. 5A-5C. Thus, repeated discussion of like features is omitted for brevity. The embodiment of FIGS. 6A-6C is different than the embodiment of FIGS. 5A-5C in that the bonding pad 113 does not include a separate bonding pad region 113b extending laterally from a side of the bonding pad region 113a. Accordingly, the bonding pad region 113a may extend over the entire area of the bonding pad 113. A via 117 of the conductive interconnect structures 109 may directly contact the bonding pad region 113a, as indicated by the dashed line in FIG. 6B. A via 117 of the conductive interconnect structures 109 may directly contact the stress buffer pad region 103, as indicated by the dashed line 118 in FIG. 6C. As in the embodiment of FIGS. 5A-5C, the minimum width dimension Da of the bonding pad 113 may be equal to the shortest distance between peripheral edges of the bonding pad 113 through the center of the bonding pad region 113a. A stress buffer pad 103 may at least partially overlie the bonding pad 113. The ratio of the minimum width dimension, Db, of the stress buffer pad 103 to the minimum width dimension, Da, of the bonding pad 113 may be at least 0.7, such as at least about 1.0. In some embodiments, Db/Da may be between 0.7 and ˜1.5.

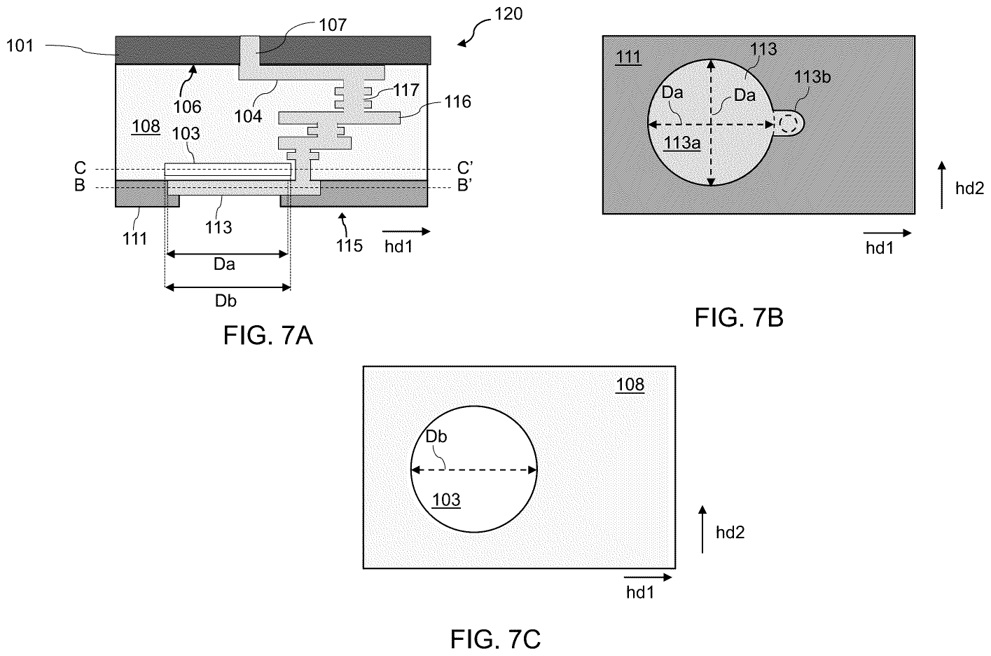

FIG. 7A is a vertical cross-section view of a portion of a package substrate 120 according to yet another embodiment of the present disclosure. FIG. 7B is a horizontal cross-section view of the portion of the package substrate taken along line B-B′ in FIG. 7A. FIG. 7C is a horizontal cross-section view of the portion of the package substrate taken along line C-C′ in FIG. 7A. The package substrate 120 of FIGS. 7A-7C is similar to the package substrate 120 described above with reference to FIGS. 4-6C. Thus, repeated discussion of like features is omitted for brevity. The package substrate 120 of FIGS. 7A-7C is different than the package substrate 120 of FIGS. 4-6C in that the stress buffer pad 103 is electrically isolated from the conductive interconnect structures 109 of the second redistribution structures 110b of the package substrate 120. In other words, the dielectric material 108 of the second redistribution structures 110b may surround the stress buffer pad 103 on all sides. The stress buffer pad 103 may be laterally offset from the conductive interconnect structure 109 (e.g., via 117) that contacts the underlying bonding pad 113. As in the previous embodiments, the ratio of the minimum width dimension, Db, of the stress buffer pad 103 to the minimum width dimension, Da, of the bonding pad 113 may be at least 0.7, such as at least about 1.0. In some embodiments, Db/Da may be between 0.7 and ˜1.5.

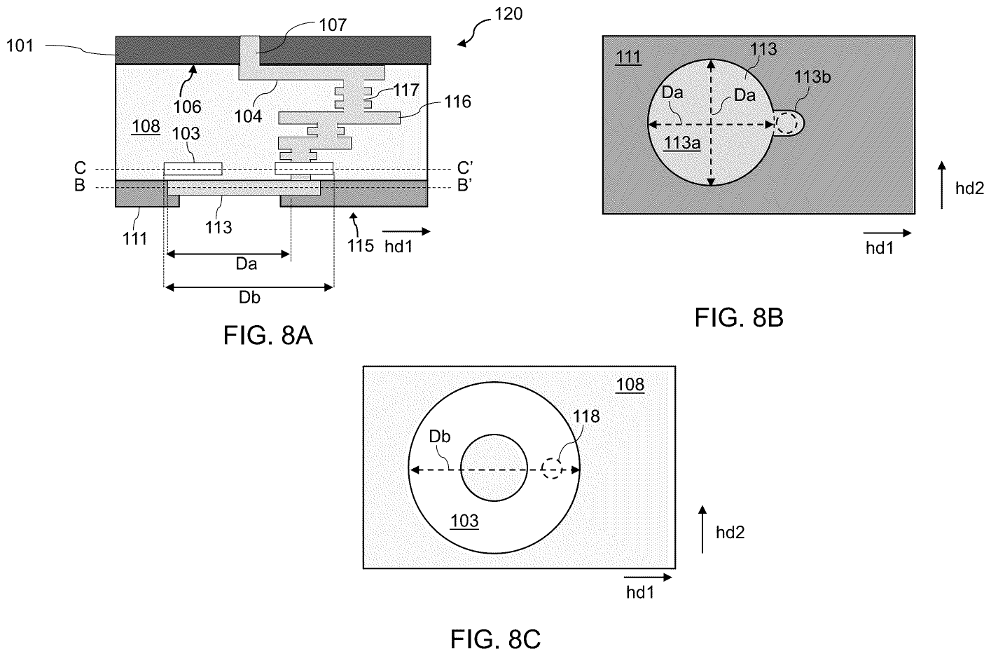

FIG. 8A is a vertical cross-section view of a portion of a package substrate 120 according to yet another embodiment of the present disclosure. FIG. 8B is a horizontal cross-section view of the portion of the package substrate taken along line B-B′ in FIG. 8A. FIG. 8C is a horizontal cross-section view of the portion of the package substrate taken along line C-C′ in FIG. 8A. The package substrate 120 of FIGS. 8A-8C is similar to the package substrate 120 described above with reference to FIGS. 4-7C. Thus, repeated discussion of like features is omitted for brevity. The package substrate 120 of FIGS. 8A-8C is different than the package substrate 120 of FIGS. 4-7C in that the stress buffer pad 103 has a ring shape with an open interior region. The open interior region may be filled with the dielectric material 108 of the second redistribution structures 110b. As in the prior embodiments, the minimum width dimension, Db, of the stress buffer pad 103 is equal to the shortest distance between peripheral edges of the stress buffer pad 103 through the geometric center of the stress buffer pad 103. The ratio of the minimum width dimension, Db, of the stress buffer pad 103 to the minimum width dimension, Da, of the bonding pad 113 may be at least 0.7, such as at least about 1.0. In some embodiments, Db/Da may be between 0.7 and ˜1.5. In the embodiment of FIGS. 8A-8C, the ring-shaped stress buffer pad 103 contacts the conductive interconnect structures 109 of the second redistribution structures 110b. A via 117 of the conductive interconnect structures 109 may directly contact the stress buffer pad region 103, as indicated by the dashed line 118 in FIG. 8C. In other embodiments, the ring-shaped stress buffer pad 103 may be electrically isolated from the conductive interconnect structures 109, as in the embodiment shown in FIGS. 7A-7C.

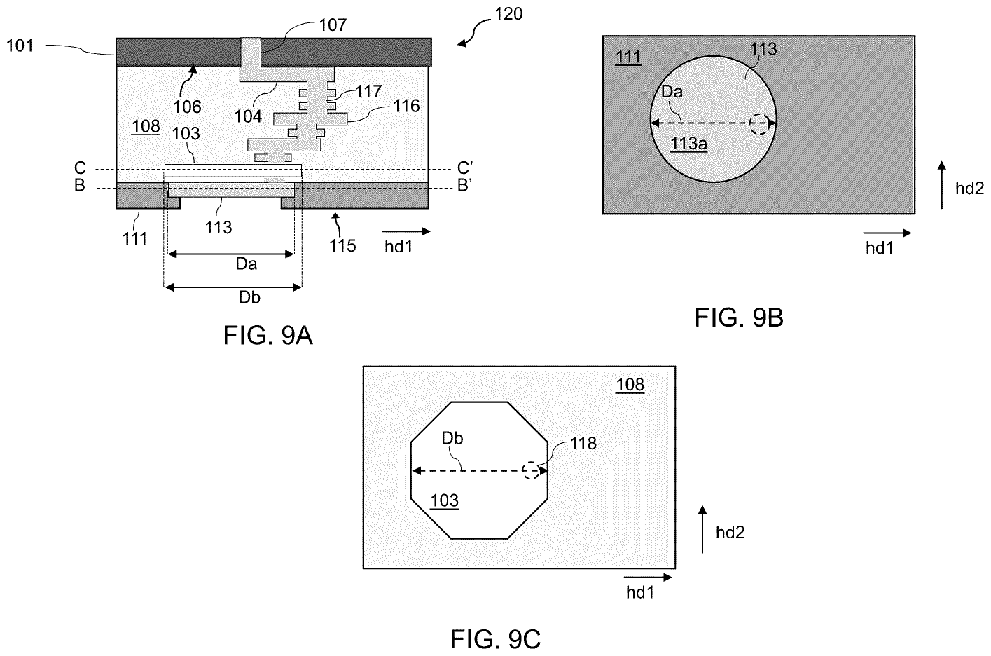

FIG. 9A is a vertical cross-section view of a portion of a package substrate 120 according to yet another embodiment of the present disclosure. FIG. 9B is a horizontal cross-section view of the portion of the package substrate taken along line B-B′ in FIG. 9A. FIG. 9C is a horizontal cross-section view of the portion of the package substrate taken along line C-C′ in FIG. 9A. The package substrate 120 of FIGS. 9A-9C is similar to the package substrate 120 described above with reference to FIGS. 4-8C. Thus, repeated discussion of like features is omitted for brevity. The package substrate 120 of FIGS. 9A-9C is different than the package substrate 120 of FIGS. 4-8C in that the stress buffer pad 103 has a polygonal shape. As in the prior embodiments, the minimum width dimension, Db, of the stress buffer pad 103 is equal to the shortest distance between peripheral edges of the stress buffer pad 103 through the geometric center of the stress buffer pad 103. The ratio of the minimum width dimension, Db, of the stress buffer pad 103 to the minimum width dimension, Da, of the bonding pad 113 may be at least 0.7, such as at least about 1.0. In some embodiments, Db/Da may be between 0.7 and ˜1.5. In the embodiment of FIGS. 9A-9C, the polygonal-shaped stress buffer pad 103 contacts the conductive interconnect structures 109 of the second redistribution structures 110b. A via 117 of the conductive interconnect structures 109 may directly contact the stress buffer pad region 103, as indicated by the dashed line 118 in FIG. 9C. In other embodiments, the polygonal-shaped stress buffer pad 103 may be electrically isolated from the conductive interconnect structures 109, as in the embodiment shown in FIGS. 7A-7C.

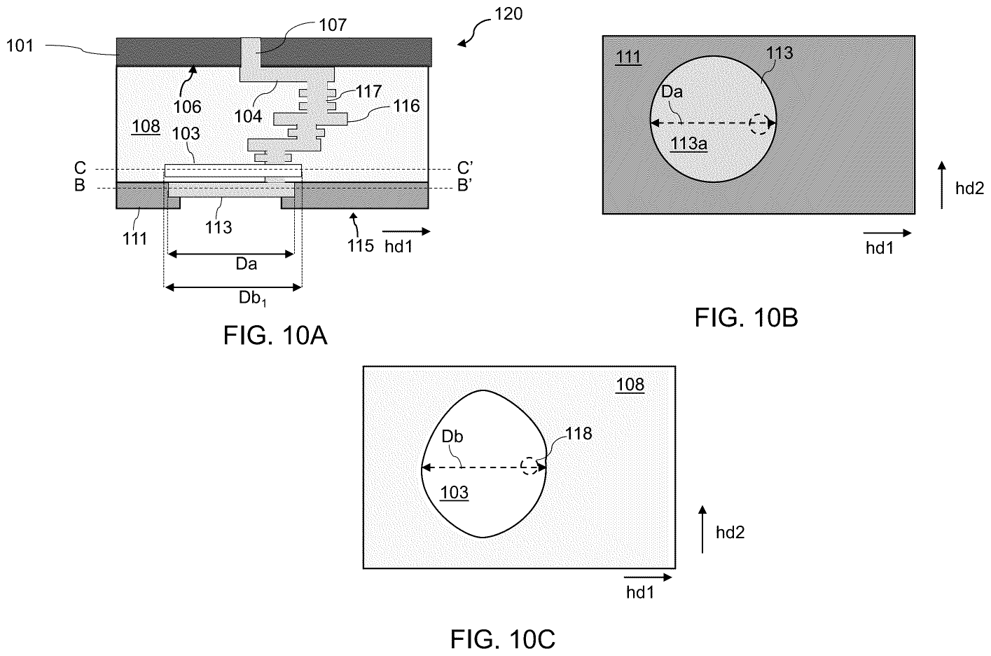

FIG. 10A is a vertical cross-section view of a portion of a package substrate 120 according to yet another embodiment of the present disclosure. FIG. 10B is a horizontal cross-section view of the portion of the package substrate taken along line B-B′ in FIG. 10A. FIG. 10C is a horizontal cross-section view of the portion of the package substrate taken along line C-C′ in FIG. 10A. The package substrate 120 of FIGS. 10A-10C is similar to the package substrate 120 described above with reference to FIGS. 4-9C. Thus, repeated discussion of like features is omitted for brevity. The package substrate 120 of FIGS. 10A-10C is different than the package substrate 120 of FIGS. 4-9C in that the stress buffer pad 103 has an irregular shape. As in the prior embodiments, the minimum width dimension, Db, of the stress buffer pad 103 is equal to the shortest distance between peripheral edges of the stress buffer pad 103 through the geometric center of the stress buffer pad 103. In this embodiment, the stress buffer pad 103 has non-unform width dimensions. The minimum width dimension, Db, of the stress buffer pad 103 is along a first horizontal direction hd1. The maximum width dimension of the stress buffer pad 103 extends along a second horizontal direction hd2. The ratio of the minimum width dimension, Db, of the stress buffer pad 103 to the minimum width dimension, Da, of the bonding pad 113 may be at least 0.7, such as at least about 1.0. In some embodiments, Db/Da may be between 0.7 and ˜1.5. In the embodiment of FIGS. 10A-10C, the irregularly-shaped stress buffer pad 103 contacts the conductive interconnect structures 109 of the second redistribution structures 110b. A via 117 of the conductive interconnect structures 109 may directly contact the stress buffer pad region 103, as indicated by the dashed line 118 in FIG. 10C. In other embodiments, the irregularly-shaped stress buffer pad 103 may be electrically isolated from the conductive interconnect structures 109, as in the embodiment shown in FIGS. 7A-7C.

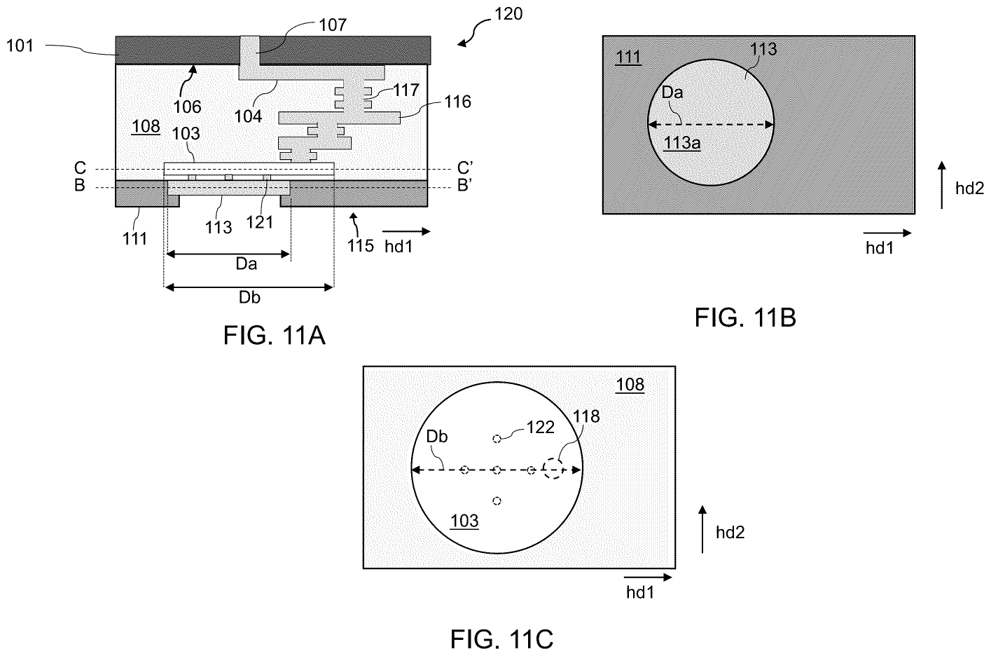

FIG. 11A is a vertical cross-section view of a portion of a package substrate 120 according to yet another embodiment of the present disclosure. FIG. 11B is a horizontal cross-section view of the portion of the package substrate taken along line B-B′ in FIG. 11A. FIG. 11C is a horizontal cross-section view of the portion of the package substrate taken along line C-C′ in FIG. 11A. The package substrate 120 of FIGS. 11A-11C is similar to the package substrate 120 described above with reference to FIGS. 4-10C. Thus, repeated discussion of like features is omitted for brevity. The package substrate 120 of FIGS. 10A-10C is different than the package substrate 120 of FIGS. 4-10C in that a via 117 of the conductive interconnect structures 109 of the second redistribution structures 110b contacts the stress buffer pad 103 in a location (indicated by dashed line 118 in FIG. 11C) that is laterally offset from the bonding pad 113. A plurality of connecting vias 121 contact the lower surface of the stress buffer pad 103 (indicated by dashed lines 122 in FIG. 11C) and electrically connect the stress buffer pad 103 to the bonding pad 113. A via 117 of the conductive interconnect structures 109 may directly contact the stress buffer pad region 103, as indicated by the dashed line 118 in FIG. 11C. As in the prior embodiments, the minimum width dimension, Db, of the stress buffer pad 103 is equal to the shortest distance between peripheral edges of the stress buffer pad 103 through the geometric center of the stress buffer pad 103. The ratio of the minimum width dimension, Db, of the stress buffer pad 103 to the minimum width dimension, Da, of the bonding pad 113 may be at least 0.7, such as at least about 1.0. In some embodiments, Db/Da may be between 0.7 and ˜1.5.

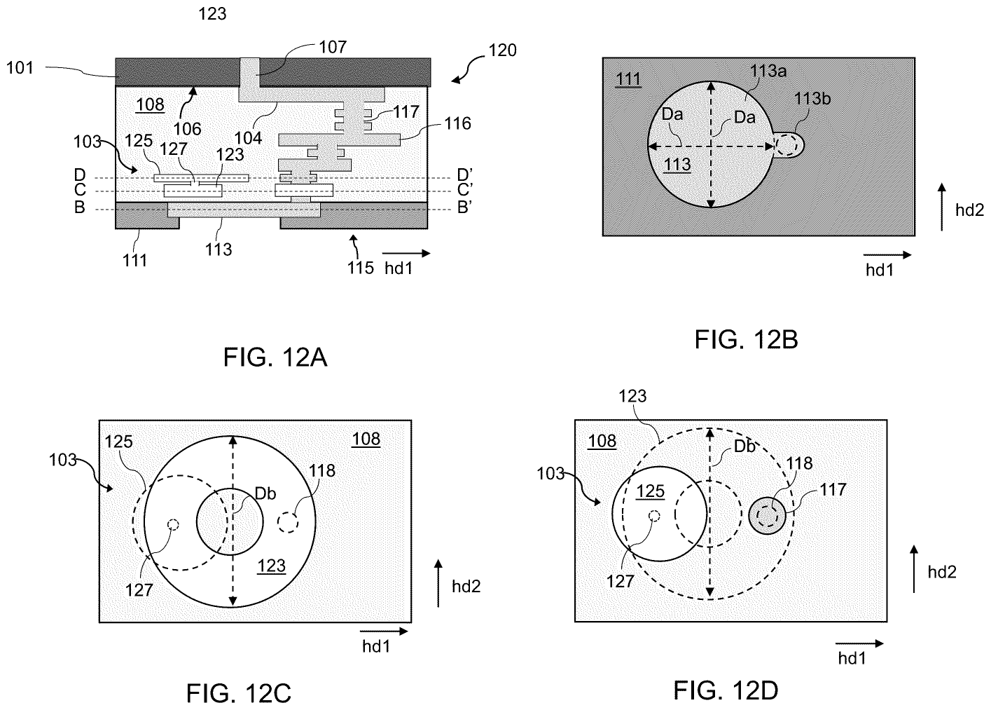

FIG. 12A is a vertical cross-section view of a portion of a package substrate 120 according to yet another embodiment of the present disclosure. FIG. 12B is a horizontal cross-section view of the portion of the package substrate taken along line B-B′ in FIG. 12A. FIG. 12C is a horizontal cross-section view of the portion of the package substrate taken along line C-C′ in FIG. 12A. FIG. 12D is a horizontal cross-section view of the portion of the package substrate taken along line D-D′ in FIG. 12A. The package substrate 120 of FIGS. 12A-12D is similar to the package substrate 120 described above with reference to FIGS. 4-11C. Thus, repeated discussion of like features is omitted for brevity. The package substrate 120 of FIGS. 12A-12D is different than the package substrate 120 of FIGS. 4-11C in that the stress buffer pad 103 includes a multi-level structure including a lower level structure 123 and an upper level structure 125 and connecting via 127. FIG. 12B includes a horizontal cross-section view of the lower level structure 123 with the upper level structure 125 indicated by a dashed line. FIG. 12C includes a horizontal cross-section view of the upper level structure 125 with the lower level structure 123 indicated by dashed lines. The lower level structure 123 and the upper level structure 125 of the stress buffer pad 103 extend in different horizontal planes that are vertically offset from one another. A connecting via 127 may connect the lower level structure 123 and the upper level structure 125. Although FIGS. 12A-12D illustrate a multi-lever stress buffer pad 103 that includes two levels, it will be understood that a multi-lever stress buffer pad 103 may include more than two levels in various embodiments.

In the embodiment shown in FIGS. 12A-12D, the lower level structure 123 of the stress buffer pad 103 has a ring-shaped structure and the upper level structure 125 of the stress buffer pad 103 has a disk-shaped structure, although it will be understood that other suitable shapes may be used for the lower level structure 123 and/or the upper level structure 125. As in the prior embodiments, the minimum width dimension, Db, of the stress buffer pad 103 is equal to the shortest distance between peripheral edges of the stress buffer pad 103 through the geometric center of the stress buffer pad 103. In this embodiment, the minimum width dimension Db is along the second horizontal direction hd2 between the peripheral edges of the lower level structure 123 of the stress buffer pad 103. The maximum width dimension of the stress buffer pad 103 is along the first horizontal direction hd1 between the peripheral edge of the upper level structure 125 and the peripheral edge of the lower level structure 123. The ratio of the minimum width dimension, Db, of the stress buffer pad 103 to the minimum width dimension, Da, of the bonding pad 113 may be at least 0.7, such as at least about 1.0. In some embodiments, Db/Da may be between 0.7 and ˜1.5. In the embodiment of FIGS. 12A-12C, the lower level structure 123 of the multi-level stress buffer pad 103 contacts the conductive interconnect structures 109 of the second redistribution structures 110b. A via 117 of the conductive interconnect structures 109 may directly contact the stress buffer pad region 103, as indicated by the dashed line 118 in FIG. 12C. In other embodiments, an upper level structure 125 of the multi-level stress buffer pad 103 may contact the conductive interconnect structures 109 of the second redistribution structures 110b, or the multi-level buffer pad 103 may be electrically isolated from the conductive interconnect structures 109.

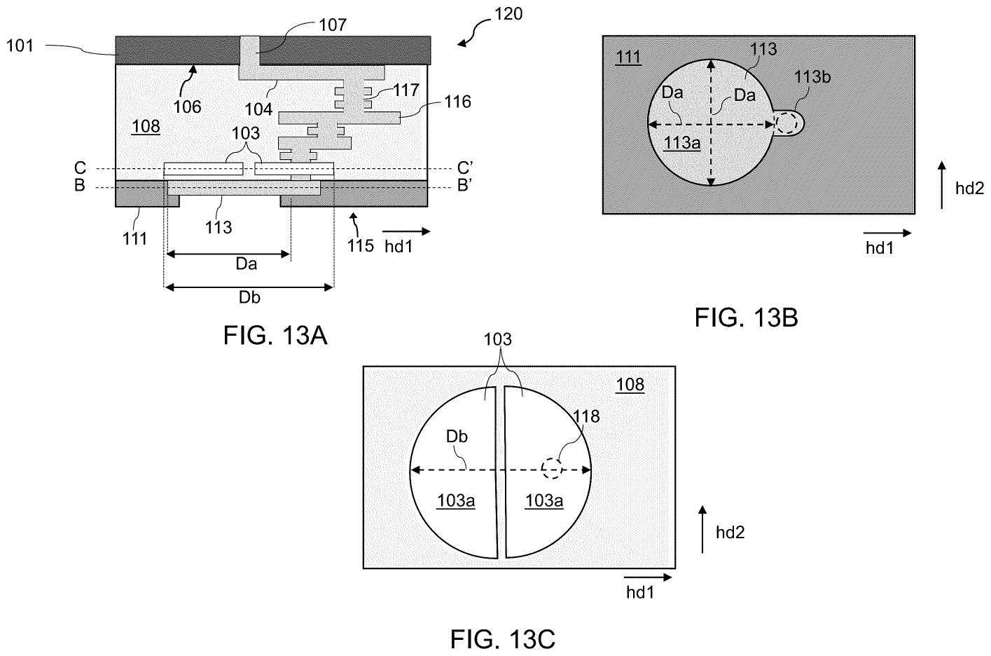

FIG. 13A is a vertical cross-section view of a portion of a package substrate 120 according to yet another embodiment of the present disclosure. FIG. 13B is a horizontal cross-section view of the portion of the package substrate taken along line B-B′ in FIG. 13A. FIG. 13C is a horizontal cross-section view of the portion of the package substrate taken along line C-C′ in FIG. 13A. The package substrate 120 of FIGS. 13A-13C is similar to the package substrate 120 described above with reference to FIGS. 4-12D. Thus, repeated discussion of like features is omitted for brevity. The package substrate 120 of FIGS. 13A-13C is different than the package substrate 120 of FIGS. 4-10 in that the stress buffer pad 103 is composed of multiple discrete segments 103a and 103b that each at least partially overlie the bonding pad 113. The embodiment of FIGS. 13A-13C illustrates a segmented stress buffer pad 103 including two semi-circular shaped segments 103a and 103b, although it will be understood that a segmented stress buffer pad 103 may include more than two discrete segments 103a and 103b, and each of the segments 103a and 103b may have different shapes. Further, although the embodiment of FIGS. 13A-13C illustrates the discrete segments 103a and 103b located in the same horizontal plane, in other embodiments, the segments 103a and 103b may be located in different horizontal planes that are vertically-spaced from one another, as with the multi-level stress buffer pad 103 described above with reference to FIGS. 12A-12D. As in the prior embodiments, the minimum width dimension, Db, of the stress buffer pad 103 is equal to the shortest distance between peripheral edges of the stress buffer pad 103 through the geometric center of the stress buffer pad 103. In the embodiment of FIGS. 13A-13C, the minimum width dimension, Db, extends between the outer periphery of a first segment 103a to the outer periphery of a second segment 103b. The ratio of the minimum width dimension, Db, of the stress buffer pad 103 to the minimum width dimension, Da, of the bonding pad 113 may be at least 0.7, such as at least about 1.0. In some embodiments, Db/Da may be between 0.7 and ˜1.5. In the embodiment of FIGS. 13A-13C, a segment 103b of the stress buffer pad 103 contacts the conductive interconnect structures 109 of the second redistribution structures 110b. A via 117 of the conductive interconnect structures 109 may directly contact the stress buffer pad region 103, as indicated by the dashed line 118 in FIG. 13C. In other embodiments, the stress buffer pad 103 may be electrically isolated from the conductive interconnect structures 109, as in the embodiment shown in FIGS. 7A-7C.

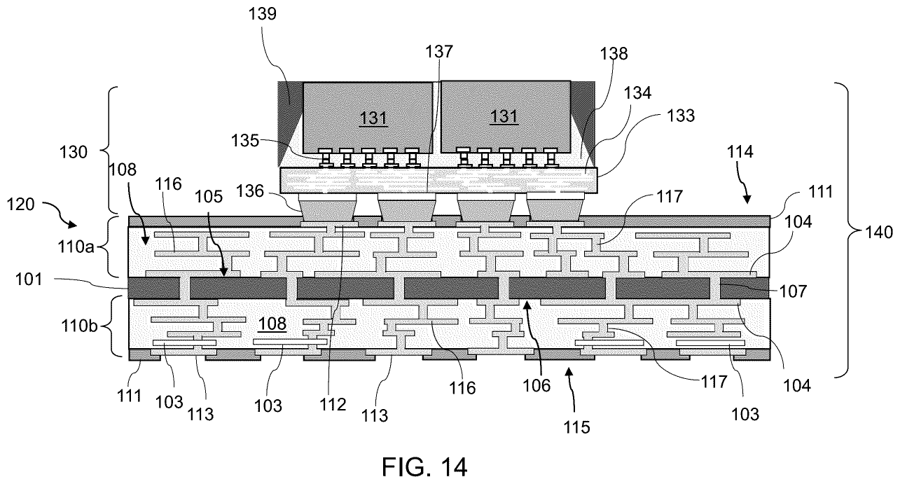

FIG. 14 is a vertical cross-section view of a semiconductor package 140 including a package structure 130 mounted over the first outer surface 114 of a package substrate 120 including a plurality of stress buffer pads 103 according to various embodiments of the present disclosure. Referring to FIG. 14, the package structure 130 may include one or more semiconductor IC dies 131. In the embodiment shown in FIG. 14, the package structure 130 includes two semiconductor IC dies 131, although it will be understood that in other embodiments a package structure 130 may include more than two semiconductor IC dies 131 or may include a single semiconductor IC die 131. The one or more semiconductor IC dies 131 of the package structure 130 may include at least one system-on-chip (SoC) die. An SoC die may include, for example, an application processor die, a central processing unit die, and/or a graphic processing unit die. In some embodiments, the one or more semiconductor IC dies 131 may include at least one memory die. The at least one memory die may include a high bandwidth memory (HBM) die. In some embodiments, a HBM die may include a vertical stack of interconnected memory dies. Alternatively, or in addition, the at least one memory die may include a dynamic random access memory (DRAM) die. In some embodiments, the package structure 130 may include a plurality of semiconductor IC dies 131 that are homogeneous, meaning that all of the semiconductor IC dies 131 may be of the same type (e.g., all SoC dies, all HBM dies, all DRAM dies, etc.). Alternatively, the package structure 130 may include a plurality of semiconductor IC dies 131 that are heterogeneous, meaning that the plurality of semiconductor IC dies 131 may include different types of semiconductor IC dies 131 (e.g., at least one SoC die and at least one memory die).

In various embodiments, the one or more semiconductor IC dies 131 of the package structure 130 may be mounted to an interposer 133, such as an organic interposer or a semiconductor (e.g., silicon) interposer. The interposer 133 may be mounted to the first outer surface 114 of the package substrate 120 to form a semiconductor package 140. The interposer 133 may include a plurality of interconnect structures 134 (e.g., metal lines and vias) within an insulating material. The one or more semiconductor IC dies 131 may be mounted to the interposer 133 via a plurality of bonding structures 135, which may include microbump (e.g., C2) bonding structures. A first underfill material portion 138 may be disposed between the one or more semiconductor IC dies 131 and the interposer 133, and may surround the bonding structures 135. A molding portion 139, which may include, for example, an epoxy mold compound (EMC), may laterally surround the one or more semiconductor IC dies 131.

Referring again to FIG. 14, a pattern of the bonding pads 112 exposed in the first outer surface 114 of the package substrate 120 may correspond to a pattern of bonding pads 137 located on a lower surface of the interposer 133. The package structure 130 may be aligned over the first outer surface 114 of the package substrate 120 such that an array of solder material portions 136 are located between the first bonding pads 112 of the package substrate 120 and the corresponding bonding pads 137 on the lower surface of the interposer 133. A reflow process may be performed to reflow the solder material portions 136, thereby inducing bonding between the interposer 133 of the package structure 130 and the package substrate 120. Each of the solder material portions 136 may be bonded to a respective one of the first bonding pads 112 of the package substrate 120 and a respective one of the bonding pads 137 on the lower surface of the interposer 133. In some embodiments, the solder material portions 136 may include C4 solder balls, and the package structure 130 may be bonded to the substrate package 120 through an array of C4 solder balls.

In alternative embodiments, the interposer 133 may be omitted, and the one or more semiconductor IC dies 131 may be directly mounted to the first outer surface 114 of the package substrate 120, such as via a plurality of microbump (e.g., C2) bonding structures.

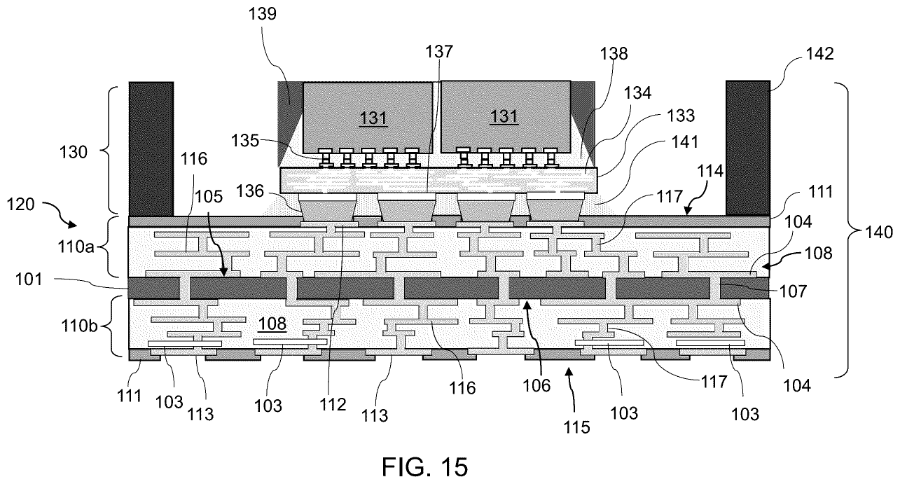

FIG. 15 is a vertical cross-section view of a semiconductor package 140 including a second underfill material portion 141 located between the first outer surface 114 of the package substrate 120 and the lower surface of the interposer 133 according to various embodiments of the present disclosure. Referring to FIG. 15, the second underfill material portion 141 may be applied into the space between the first outer surface 114 of the package substrate 120 and the lower surface of the interposer 133. The second underfill material portion 141 may laterally surround and contact each of the solder material portions 136 that bond the interposer 133 to the package substrate 120. A stiffening structure 142, such as a ring structure and/or a lid structure may be mounted to the first outer surface 114 of the package substrate 120 and laterally surrounding the package structure 130.

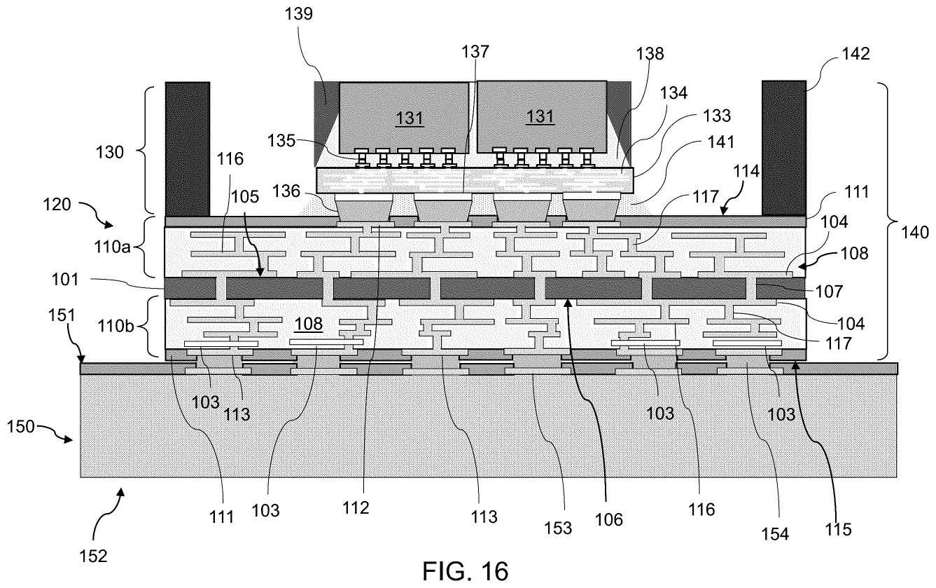

FIG. 16 is a vertical cross-section view of a semiconductor package 140 mounted to a supporting substrate 150 according to various embodiments of the present disclosure. Referring to FIG. 16, the supporting substrate 150 may be a PCB including an array of bonding pads 153 exposed through an upper surface 151 of the supporting substrate 150. The pattern of bonding pads 113 on the second surface 115 of the package substrate 120 may correspond to the pattern of bonding pads 153 on the upper surface 151 of the supporting substrate 150. The semiconductor package 140 may be aligned over the upper surface 151 of the support substrate 150 such that an array of solder material portions 154 are located between the bonding pads 113 on the second surface 115 of the package substrate 120 and the corresponding bonding pads 153 on the upper surface 151 of the supporting substrate 150. A reflow process may be performed to reflow the solder material portions 154, thereby inducing bonding between the package substrate 120 of the semiconductor package 140 and the supporting substrate 150. Each of the solder material portions 154 may be bonded to a respective one of the bonding pads 113 on the second surface 115 of the package substrate 120 and a respective one of the bonding pads 153 on the upper surface 151 of the supporting substrate 150. As discussed above, a stress buffer pad 103 may overlie at least some of the bonding pads 113 on the second surface 115 of the package substrate 120.

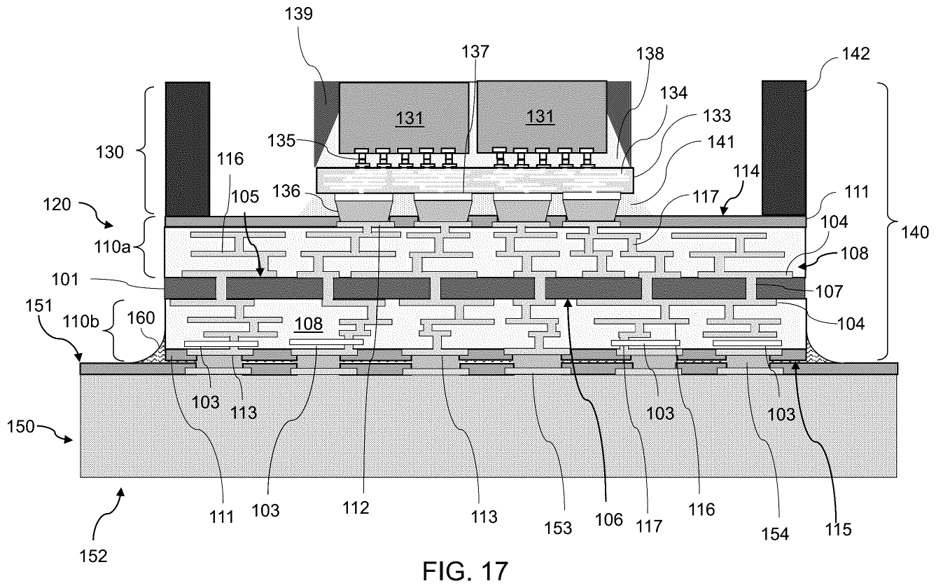

FIG. 17 is a vertical cross-section view of a semiconductor package 140 mounted to a supporting substrate 150 including a third underfill material portion 160 according to various embodiments of the present disclosure. In some embodiments, an optional third underfill material portion 160 may be applied into the space between the second side 115 of the package substrate 120 and the upper surface 151 of the supporting substrate 150. The third underfill material portion 160 may laterally surround and contact each of the solder material portions 154 that bond the package substrate 120 to the supporting substrate 150.

Referring again to FIGS. 16 and 17, the semiconductor package 140 according to various embodiments includes a package structure 130 including one or more semiconductor IC dies 131 mounted to a first outer surface 114 of a package substrate 120. A second surface 115 of the package substrate 120 is mounted to an upper surface 151 of a supporting substrate 150, such as a PCB, via a plurality of solder material portions 154 extending between bonding pads 113 on the second surface 115 of the package substrate 120 and bonding pads 153 on the upper surface 151 of the supporting substrate 150. Stress buffer pads 103 are located over at least some of the bonding pads 113 on the second surface 115 of the package substrate 120. The stress buffer pads 103 may relieve stress on the package substrate 120 and inhibit warpage and crack formation in the package substrate 120.

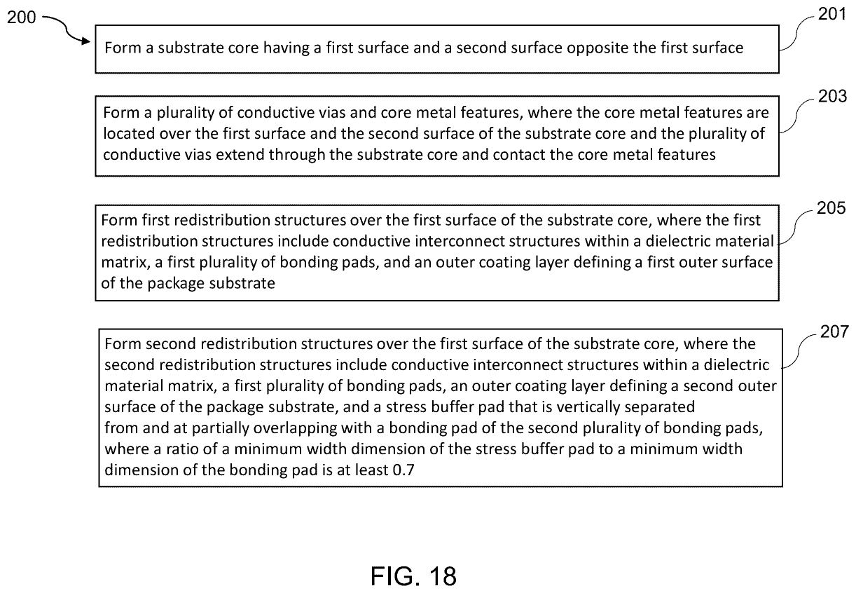

FIG. 18 is a flowchart illustrating a method 200 of fabricating a package substrate 120 according to various embodiments of the present disclosure. Referring to FIGS. 1 and 18, in step 201 of embodiment method 200, a substrate core 101 including a first surface 105 and a second surface 106 opposite the first surface 105 may be formed. Referring to FIGS. 2 and 18, in step 203 of embodiment method 200, a plurality of conductive vias 107 and core metal features 104 may be formed, where the core metal features 104 are located over the first surface 105 and the second surface 106 of the substrate core 101 and the plurality of conductive vias 107 extend through the substrate core 101 and contact the core metal features 104.

Referring to FIGS. 3 and 18, in step 205 of embodiment method 200, first redistribution structures 110a may be formed over the first surface 105 of the substrate core 101, where the first redistribution structures 110a include conductive interconnect structures 109 within a dielectric material 108, a first plurality of bonding pads 112, and an passivation layer 111 defining a first outer surface 114 of the package substrate 120.

Referring to FIGS. 4-13C and 18, in step 207 of embodiment method 200, second redistribution structures 110b may be formed over the first surface 105 of the substrate core 101, where the second redistribution structures 110b include conductive interconnect structures 109 within a dielectric material 108, a second plurality of bonding pads 113, a passivation layer 111 defining a second outer surface 115 of the package substrate 120, and a stress buffer pad 103 that is vertically separated from and at partially overlapping with a bonding pad 113 of the second plurality of bonding pads 113, where a ratio of a minimum width dimension, Db, of the stress buffer pad 103 to a minimum width dimension, Da, of the bonding pad 113 is at least 0.7.

Referring to all drawings and according to various embodiments of the present disclosure, a substrate 120 for a semiconductor package 140 may include a substrate core 101, and redistribution structures 110b over a surface 106 of the substrate core 101, where the redistribution structures 110b include conductive interconnect structures 109 within a dielectric material 108, a bonding pad 113, and a stress buffer pad 103 that is vertically separated from the bonding pad 113, where the stress buffer pad 103 is located more proximate to the bonding pad 113 than to the surface of the substrate core 101.

In an embodiment, a ratio of a minimum width dimension Db of the stress buffer pad 103 to a minimum width dimension Da of the bonding pad is at least 0.7.

In another embodiment, a vertical separation between the bonding pad 113 and the stress buffer pad 103 is between 20 μm and 40 μm, and the dielectric material 108 of the redistribution structures 110b is located between the bonding pad 113 and the stress buffer pad 103.

In another embodiment, the ratio of the minimum width dimension Db of the stress buffer pad 103 to the minimum width dimension Da of the bonding pad 113 is less than 1.5.

In another embodiment, the ratio of the minimum width dimension Db of the stress buffer pad 103 to the minimum width dimension of the bonding pad 113 is at least 1.0.

In another embodiment, the stress buffer pad 103 is electrically coupled to the conductive interconnect structures 109 of the redistribution structures 110b and to the bonding pad 113.

In another embodiment, the substrate 120 further includes a solder resist layer 111 covering a portion of the bonding pad 113.

In another embodiment, the stress buffer pad 103 is electrically isolated from the conductive interconnect structures 109 of the redistribution structures 110b and the bonding pad 113.

In another embodiment, the stress buffer pad 103 and the bonding pad 113 are composed of the same material.

In another embodiment, the stress buffer pad 103 is composed of a material having a higher Young's modulus than the Young's modulus of the material of the bonding pad 113.

In another embodiment, the bonding pad 113 is composed of a metal material and the stress buffer pad 103 is composed of a ceramic and/or a semiconductor material.

In another embodiment, the stress buffer pad includes a disk shape, a ring shape, a polygonal shape or an irregular shape.

In another embodiment, the stress buffer pad 103 includes a multi-level stress buffer pad 103 that includes a lower level structure 123 and an upper level structure 125 that extend in different horizontal planes that are vertically offset from one another.

In another embodiment, the stress buffer pad 103 includes multiple discrete segments 103a, 103b that each at least partially overlap with the bonding pad 113.

An additional embodiment is drawn to a semiconductor package 140 including a semiconductor package structure 130 having one or more semiconductor integrated circuit (IC) dies 131, a package substrate 120 including a plurality of bonding pads 113 and a plurality of stress buffer pads 103, where each stress buffer pad 103 is vertically separated from and at least partially overlaps a corresponding bonding pad 113 of the plurality of bonding pads 113, and a supporting substrate 150, wherein the semiconductor package structure 140 is mounted to a first side 114 of the package substrate 120 and a second side of the package substrate 120 is mounted to the supporting substrate 150.

In an embodiment, the package substrate 120 includes a substrate core 101 located between the first side 114 and the second side 115 of the package substrate 120, and the plurality of stress buffer pads 103 are located more proximate to the plurality of bonding pads 113 than to the substrate core 101, and where the ratio of the minimum width dimension of each stress buffer pad 103 to the minimum width dimension of the corresponding bonding pad 113 is at least 0.7.

In another embodiment, the semiconductor package 140 further includes a solder resist layer 111 on the second side 115 of the package substrate 120, where the plurality of bonding pads 113 are exposed through openings in the solder resist layer 111.

In another embodiment, the semiconductor package structure 130 includes an interposer 133, and a plurality of semiconductor IC dies 131 mounted to an upper surface of the interposer 133, and the semiconductor package structure 130 is mounted to the first side 114 of the package substrate 120 via a plurality of solder connections 136 extending between a lower surface of the interposer 133 and the first side 114 of the package substrate 120, and where the supporting substrate 150 includes a printed circuit board (PCB) 150 and the package substrate 120 is mounted to the PCB 150 via a plurality of solder connections 154 extending between the plurality of bonding pads 113 on the second side 115 of the package substrate 120 and an upper surface 151 of the PCB 150.

An additional embodiment is drawn to a method of fabricating a package substrate that includes forming a conductive interconnect structure 109 within a dielectric material 108 over a surface of a substrate core 101, forming a stress buffer pad 103 over the conductive interconnect structure 109, forming a bonding pad 113 over the stress buffer pad 103, where the stress buffer pad 103 is vertically separated from and at least partially overlapping with the bonding pad 113, and forming a passivation layer 111 covering a portion of the bonding pad 103.

In an embodiment, where a ratio of a minimum width dimension Db of the stress buffer pad 103 to a minimum width dimension Da of the bonding pad 113 is at least 0.7.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A substrate for a semiconductor package, comprising:
a substrate core; and
redistribution structures over a surface of the substrate core, wherein the redistribution structures comprise:
conductive interconnect structures within a dielectric material;
a bonding pad; and
a stress buffer pad vertically separated from the bonding pad, wherein the stress buffer pad is located more proximate to the bonding pad than to the surface of the substrate core.

2. The substrate of claim 1, wherein a ratio of a minimum width dimension of the stress buffer pad to a minimum width dimension of the bonding pad is at least 0.7.

3. The substrate of claim 1, wherein a vertical separation between the bonding pad and the stress buffer pad is between 20 μm and 40 μm, and the dielectric material of the redistribution structures is located between the bonding pad and the stress buffer pad.

4. The substrate of claim 1, wherein the ratio of the minimum width dimension of the stress buffer pad to the minimum width dimension of the bonding pad is less than 1.5.

5. The substrate of claim 1, wherein the ratio of the minimum width dimension of the stress buffer pad to the minimum width dimension of the bonding pad is at least 1.0.

6. The substrate of claim 1, wherein the stress buffer pad is electrically coupled to the conductive interconnect structures of the redistribution structures and to the bonding pad.

7. The substrate of claim 1, further comprising a solder resist layer covering a portion of the bonding pad.

8. The substrate of claim 1, wherein the stress buffer pad is electrically isolated from the conductive interconnect structures of the redistribution structures and the bonding pad.

9. The substrate of claim 1, wherein the stress buffer pad and the bonding pad are composed of the same material.

10. The substrate of claim 1, wherein the stress buffer pad is composed of a material having a higher Young's modulus than the Young's modulus of the material of the bonding pad.

11. The substrate of claim 1, wherein the bonding pad is composed of a metal material and the stress buffer pad is composed of a ceramic and/or a semiconductor material.

12. The substrate of claim 1, wherein the stress buffer pad comprises a disk shape, a ring shape, a polygonal shape or an irregular shape.

13. The substrate of claim 1, wherein the stress buffer pad comprises a multi-level stress buffer pad that includes a lower level structure and an upper level structure that extend in different horizontal planes that are vertically offset from one another.

14. The substrate of claim 1, wherein the stress buffer pad comprises multiple discrete segments that each at least partially overlap with the bonding pad.

15. A semiconductor package, comprising:
a semiconductor package structure comprising one or more semiconductor integrated circuit (IC) dies;
a package substrate comprising a plurality of bonding pads and a plurality of stress buffer pads, wherein each stress buffer pad is vertically separated from and at least partially overlaps a corresponding bonding pad of the plurality of bonding pads; and
a supporting substrate, wherein the semiconductor package structure is mounted to a first side of the package substrate and a second side of the package substrate is mounted to the supporting substrate.

16. The semiconductor package of claim 15, wherein the package substrate comprises a substrate core located between the first side and the second side of the package substrate, and the plurality of stress buffer pads are located more proximate to the plurality of bonding pads than to the substrate core, and wherein the ratio of the minimum width dimension of each stress buffer pad to the minimum width dimension of the corresponding bonding pad is at least 0.7.

17. The semiconductor package of claim 16, further comprising:
a solder resist layer on the second side of the package substrate, wherein the plurality of bonding pads are exposed through openings in the solder resist layer.

18. The semiconductor package of claim 16, wherein the semiconductor package structure comprises:
an interposer; and
a plurality of semiconductor IC dies mounted to an upper surface of the interposer, and the semiconductor package structure is mounted to the first side of the package substrate via a plurality of solder connections extending between a lower surface of the interposer and the first side of the package substrate, and
wherein the supporting substrate comprises a printed circuit board (PCB) and the package substrate is mounted to the PCB via a plurality of solder connections extending between the plurality of bonding pads on the second side of the package substrate and an upper surface of the PCB.

19. A method of fabricating a package substrate, comprising:
forming a conductive interconnect structure within a dielectric material over a surface of a substrate core;
forming a stress buffer pad over the conductive interconnect structure;
forming a bonding pad over the stress buffer layer, wherein the stress buffer pad is vertically separated from and at least partially overlapping with the bonding pad; and
forming a passivation layer covering a portion of the bonding pad.

20. The method of claim 19, wherein a ratio of a minimum width dimension of the stress buffer pad to a minimum width dimension of the bonding pad is at least 0.7.
